(19) United States
(12) Patent Application Publication
(10) Pub. No.: US 2026/0082477 A1
(43) Pub. Date: Mar. 19, 2026

(54) TESTING SYSTEM FOR COMPUTING HARDWARE INCLUDING INTEGRATED CIRCUIT EMULATION

(71) Applicant: Microsoft Technology Licensing, LLC, Redmond, WA (US)

(72) Inventors: David Hugh PRICE, Battle Ground, WA (US); Joey YUEN, Kirkland, WA (US); Jonathan Taylor KEY, Seattle, WA (US); Saadiah Gul AHMED, Lynnwood, WA (US); Mitzi GARCIA CERVANTES, Beaverton, OR (US); Gaurav RAJASEKAR, Sammamish, WA (US); Farzin M. NASERY, Portland, OR (US); Nabil Amir RIZK, Apex, NC (US); Meng ZHAO, Raleigh, NC (US); Lam Tan NGO, Raleigh, NC (US); Thanh Cong DINH, San Jose, CA (US); Scott David WALDRON, Atherton, CA (US)

(21) Appl. No.: 18/885,317

(22) Filed: Sep. 13, 2024

(51) Int. Cl. H05K 1/02; G06F 1/18; H05K 1/18

(52) U.S. Cl. CPC H05K 1/0268; G06F 1/185; H05K 1/18; H05K 2201/10378

(57) ABSTRACT

In various examples, a computing system with a printed circuit assembly including a socket coupled to an interposer to allow the testing of various components of the printed circuit assembly is provided. For example, the interposer includes a connector that is coupled with the adapter board and allows communication between the adapter board and the printed circuit assembly. In one example, the adapter board is connected to an emulation system that emulates an integrated circuit component such as a System on a Chip (SoC). In other examples, the adapter board includes components that test hardware and software of the printed circuit assembly.

### BACKGROUND

Computing devices typically have a printed circuit assembly, such as a motherboard, with an integrated circuit component or processor, such as a central processing unit, or a System on a Chip (SoC) and other electronic components, such as a voltage regulator. Development of these types of computing hardware is challenging, as they are typically developed in parallel and require validation and testing individually and together. For example, in order to avoid delays, development of a new generation of printed circuit assemblies and SoCs requires validation and testing of the new generation of printed circuit assemblies prior to completion of development of the SoC.

### SUMMARY

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

Embodiments described in the present disclosure are directed towards technologies for improving development cycles and testing of printed circuit assemblies (e.g., a motherboard including a socket for accepting a processor such as a System on a Chip [SoC]), thereby reducing development costs and time required to develop and release new computing systems (such as server computer systems, consumer electronics, artificial intelligence systems, or various other types of computing systems). In particular, embodiments provide an interposer that can be inserted into a socket of the printed circuit assembly, the interposer including a connector to attach one or more adapter boards that can be used to perform various testing functions. In one example, the interposer is connected to an emulation adapter board that is connected to a server computer system that emulates a processor, such as an SoC.

### BRIEF DESCRIPTION OF THE DRAWINGS

Aspects of the disclosure are described in detail below with reference to the attached drawing figures, wherein:

FIG. 1 illustrates an environment in which a printed circuit assembly includes an interposer connected to an adapter board connected to an emulation system, in accordance with an embodiment of the present disclosure;

FIGS. 2A and 2B is a schematic perspective view of a printed circuit assembly including an interposer and an adapter board, in accordance with an embodiment of the present disclosure;

FIG. 3 depicts a partial cross-sectional view of a printed circuit assembly including an interposer and an adapter board of FIGS. 2A and 2B, in accordance with an embodiment of the present disclosure;

FIG. 4A is a schematic perspective view of a printed circuit assembly including a shim covering an interposer, in accordance with an embodiment of the present disclosure;

FIG. 4B is a schematic perspective view of a printed circuit assembly including a socket lid, in accordance with an embodiment of the present disclosure;

FIG. 5A is a schematic perspective view of a printed circuit assembly including a socket lid and an adapter board, in accordance with an embodiment of the present disclosure;

FIG. 5B is a partial cross-sectional view of an adapter board of FIG. 5A, in accordance with an embodiment of the present disclosure;

FIG. 6 illustrates an environment in which a printed circuit assembly includes an interposer connected to an adapter board to testing various components of the printed circuit assembly, in accordance with an embodiment of the present disclosure

FIGS. 7A-7C depict schematic views of a server chassis and components, in accordance with an embodiment of the present disclosure; and

FIG. 8 is a block diagram of an exemplary computing environment suitable for use in implementations of the present disclosure.

### DETAILED DESCRIPTION

The subject matter of aspects of the present disclosure is described with specificity herein to meet statutory requirements. However, the description itself is not intended to limit the scope of this patent. Rather, the inventors have contemplated that the claimed subject matter might also be embodied in other ways, in conjunction with other present or future technologies.

Embodiments described herein generally relate to aspects of a computing system that includes a printed circuit assembly with an interposer coupled to a socket of the printed circuit assembly, where the interposer is connected to an adapter board that allows for testing on various components of the printed circuit assembly (e.g., voltage regulator, memory, firmware, various interfaces, etc.). In accordance with some aspects, the systems and methods described are directed to an adapter board that is connected to an emulation system that emulates a processor such as a System on a Chip (SoC). For example, during development and testing of a new printed circuit assembly and new SoC (e.g., development a new processor prior to production of the physical processor), the new printed circuit assembly is connected via the interposer and adapter board to the emulation system that emulates the new SoC in order to test the components of the printed circuit assembly. In other words, during development of computing systems including printed circuit assemblies and processors, it is advantageous to test interactions between the printed circuit assemblies, the components thereof, and processors coupled to the printed circuit assembly prior to production of the processors.

Other solutions require the development a production of interposers that can connect previous iterations, versions, or types of processors. For example, the current or previous generation of the new processor that is in development (e.g., prior to production on the physical processor). However, this increases development cost and time, and previous processors are not equivalent to the new processor in development and are not intended to be used with the printed circuit assembly. Aspects of the technology described herein provide a number of improvements over existing technologies. For instance, the technology allows for emulation of the processor intended to be coupled to the printed circuit assembly, thereby reducing costs and development time incurred by waiting for the production and testing of other dependencies.

Traditionally, hardware manufactures utilize a previous or current generation integrated circuit components (e.g., SoC) to validate and test the new generation of printed circuit assembly, as the new generation of integrated circuit components are not available yet. This requires the development of an interface to attach the previous or current generation integrated circuit components to the new generation of printed circuit assembly.

However, the previous or current generation integrated circuit components are not equivalent to the new integrated circuits components being developed. Furthermore, development of the interface to attach the previous or current generation integrated circuit components to the new generation of printed circuit assembly cost additional time and resources. Additionally, this traditional method is not an option for novel components such as SoCs or other novel processors. Finally, these traditional methods of testing are dependent on development timelines for the firmware, operating system, socket, and integrated circuits.

Furthermore, various embodiments of the present disclosure relate to an integrated circuit socket configured for coupling to a printed circuit assembly and to accept an integrated circuit component, the socket including a socket back plate for coupling to the printed circuit assembly and a socket lid coupled to the top of the integrated circuit socket; at least one electronic component configured for coupling to the printed circuit assembly; an adapter board configured for coupling to a computing system operating an emulation application; and an interposer coupled to the socket so that, when the socket is coupled to the printed circuit assembly, the interposer is positioned between the printed circuit assembly and the socket lid, the interposer including a connector to accept the adapter board. As described in the present disclosure, the adapter boards described, including the emulation adapter board, in various embodiments, include printed circuit assemblies.

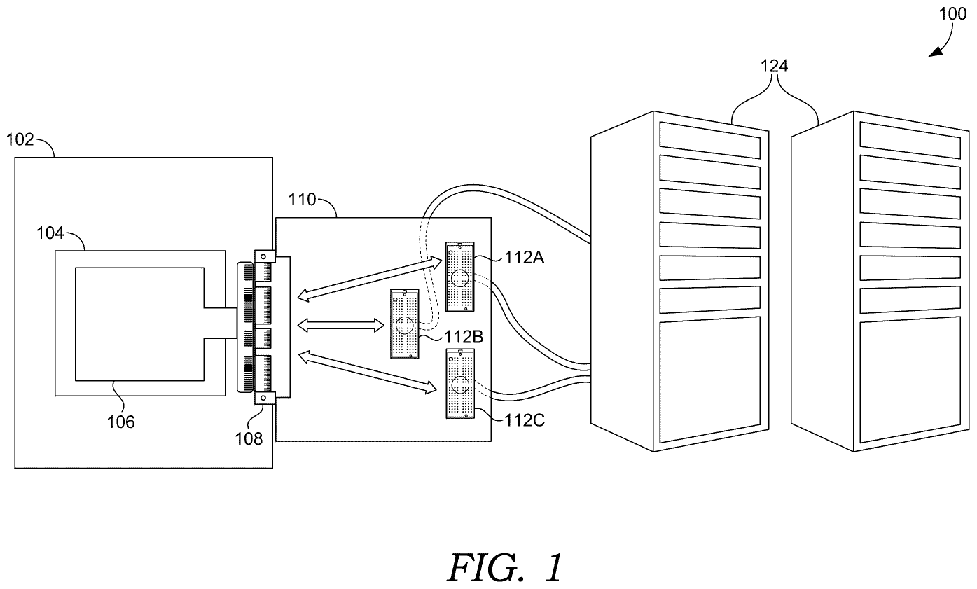

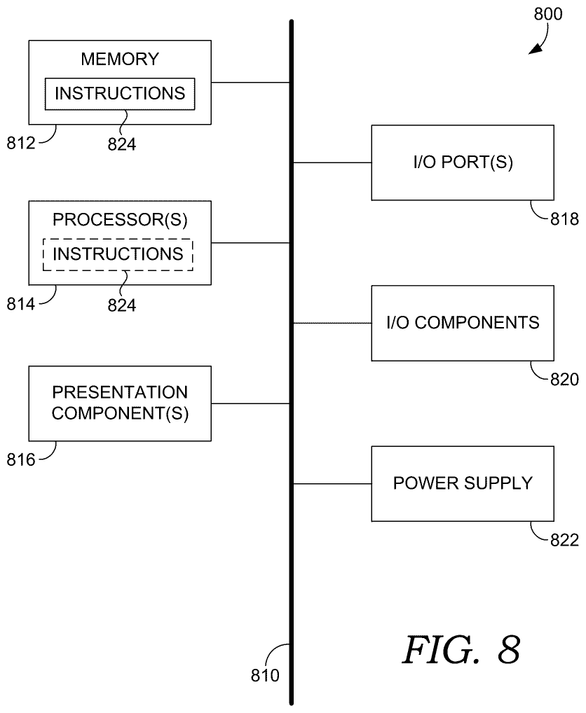

Turning to FIG. 1, FIG. 1 is a diagram of an environment 100 in which one or more embodiments of the present disclosure can be practiced. It should be understood that this and other arrangements described herein are set forth only as examples. Other arrangements and elements (e.g., machines, interfaces, functions, orders, and groupings of functions, etc.) can be used in addition to or instead of those shown, and some elements can be omitted altogether for the sake of clarity. Further, many of the elements described herein are functional entities that can be implemented as discrete or distributed components or in conjunction with other components, and in any suitable combination and location. Various functions described herein as being performed by one or more entities can be carried out by hardware, firmware, and/or software. For instance, some functions can be carried out by a processor executing instructions stored in memory, as further described with reference to FIG. 8.

It should be understood that environment 100 shown in FIG. 1 is an example of one suitable environment. Among other components not shown, operating environment 100 includes a computing system including a printed circuit assembly 102, adapter board 110, and an emulation system 124. Each of the components shown in FIG. 1 can be implemented via any type of computing device, such as one or more computing devices 800 described in connection with FIG. 8, for example. In some embodiments, these components can communicate with each other via an interface, which can be wired (e.g., a physical connection), wireless (e.g., a network), or both.

It should be understood that any number of devices, servers, and other components can be employed within operating environment 100 within the scope of the present disclosure. Each can comprise a single device or multiple devices cooperating in a distributed environment. For example, the emulation system 124 includes multiple server computer systems cooperating in a distributed environment to perform the operations described in the present disclosure. In various embodiments, the emulation system 124 includes one or more processors, and one or more computer-readable media that include computer-readable instructions executable by the one or more processors. In an embodiment, the instructions are embodied by an emulation application that emulates the operations and/or instruction architecture of a processor such as an SoC. In one example, the emulation application is referred to as a single application for simplicity, but its functionality can be embodied by one or more applications in practice. In various embodiments, the emulation application includes any application capable of emulating a processor and facilitating the exchange of information between the computing system, including the printed circuit assembly 102 and the emulation system 124 (e.g., via the adapter board 110).

As described in greater detail below, in various embodiments, the printed circuit assembly 102 includes a socket 104, an interposer 106, and a connector 108. In one example, the printed circuit assembly 102 includes a motherboard. In various embodiments, the printed circuit assembly 102 includes a top and a bottom, where the socket 104 is integrated into the top of the printed circuit assembly 102 and can be used to couple an integrated circuit component to the printed circuit assembly 102. In an embodiment, the socket 104 (e.g., an integrated circuit socket and/or a central processing unit [CPU] socket) includes a physical interface that connects the integrated circuit component (e.g., an SoC, CPU, artificial intelligence device, or other processor) to the printed circuit assembly 102. In one example, the socket 104 includes an array of pins and a securing mechanism that holds the processor in place. Continuing this example, the socket 104 enables communication between the printed circuit assembly 102 and the integrated circuit component coupled to the socket 104.

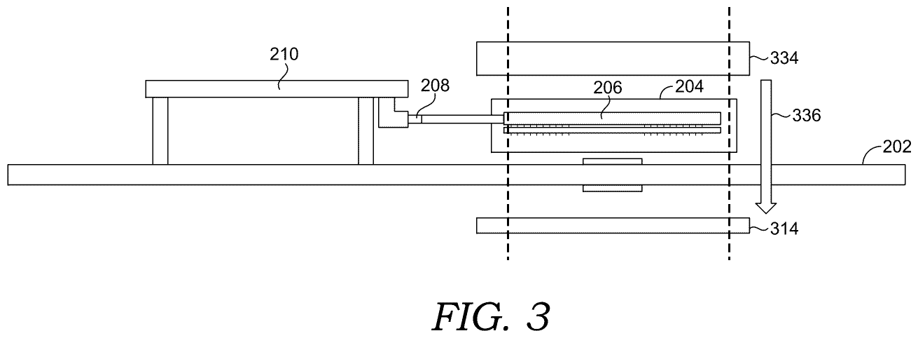

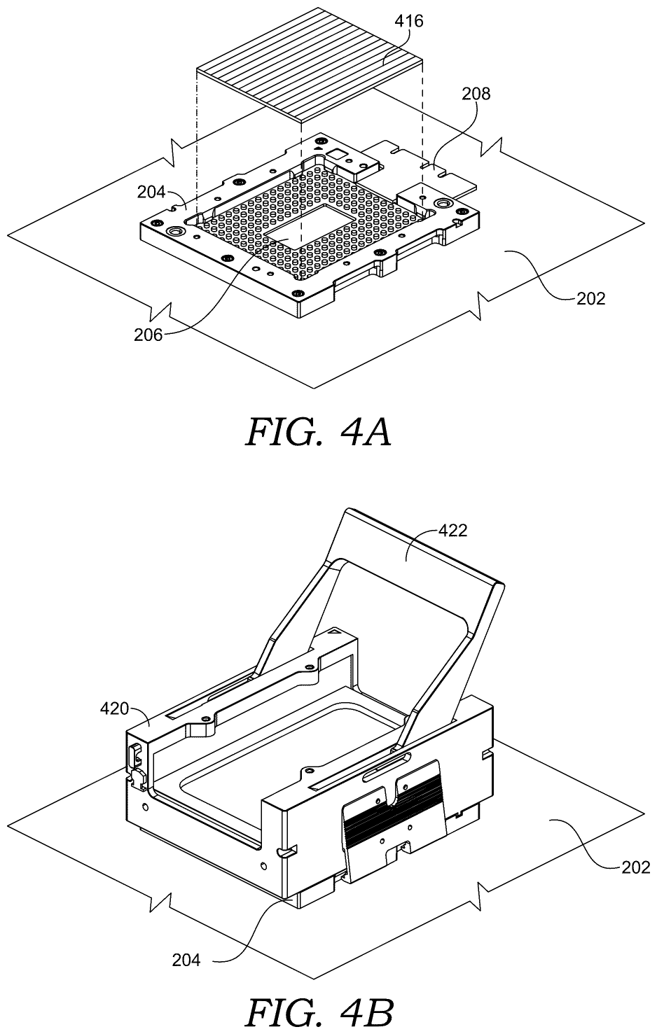

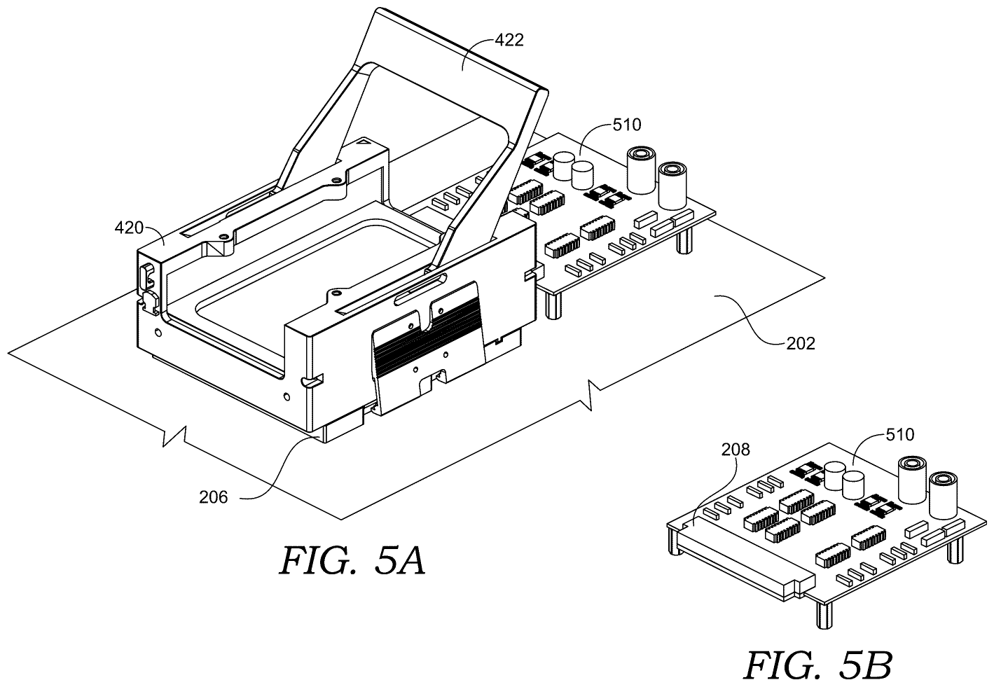

In various embodiments, the interposer 106 is coupled to the socket 104. For example, the interposer 106 provides an interface (e.g., the connector 108) that enables communication via the adapter board 110 to other components (e.g., the emulation system 124). In various embodiments, the interposer 106 includes a set of contact elements that align and mate with the array of pins in the socket 104. Furthermore, in some embodiments, the interposer 106 has a different thickness and, as a result, uses a different compression system for affixing the interposer 106 to the printed circuit assembly 102. In one example, a socket lid, such as the socket lid 420, as described below in connection with FIGS. 4 and 5, is used to provide the appropriate compression force (e.g., forty grams per contact). Furthermore, as illustrated in FIG. 3, in various embodiments, the interposer 106 includes a component, such as a backplate, integrated with the back of the printed circuit assembly 102.

Furthermore, in various embodiments, the interposer 106 includes the connector 108 that includes an interface and a set of pins to accept the adapter board 110. In one example, the connector 108 includes a 168-pin straddle-mount connector. In various embodiments, the adapter board 110 is coupled to the connector 108 and enables testing of various components of the printed circuit assembly 102 (e.g., hardware, software, interfaces, connections, dependencies, etc.).

In the environment 100 illustrated in FIG. 1, the adapter board 110 includes a plurality of input/output (I/O) ports 112A-112C that are connected (e.g., via a cable) to the emulation system. For example, the I/O ports 112A-112C allow communication between the printed circuit assembly 102 and the emulation system 124. For example, a cable is used to connect the adapter board to the emulation system 124. Although the adapter board 110 illustrated in FIG. 1 includes the I/O ports 112A-112C, other configurations and components of the adapter board 110 can be used in connection with the present disclosure (e.g., the adapter board 510 illustrated in FIGS. 5A and 5B).

In various embodiments, the adapter board 110 provides an interface to communicate via the interposer 106 to the printed circuit assembly 102. For example, the adapter board 110 is used to test components of the computer system and/or the processor (e.g., SoC) emulated by the emulation system 124.

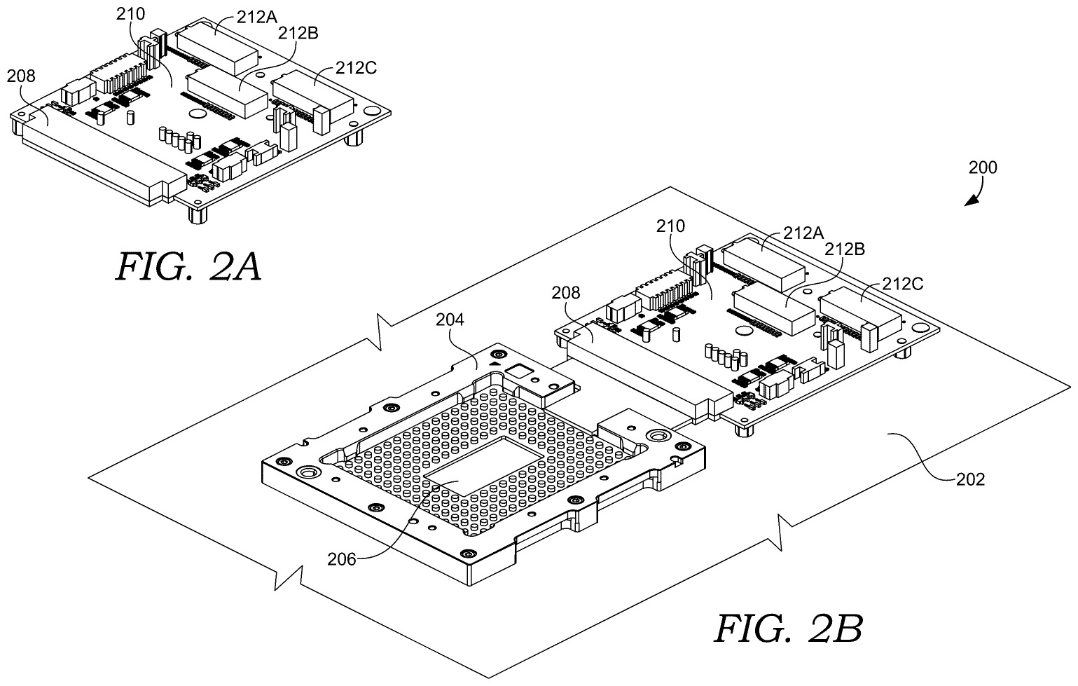

Turning now to FIGS. 2A and 2B, FIGS. 2A and 2B shows a perspective view of a computing system 200, such as a computing system illustrated in environment 100 described above in connection with FIG. 1, in which some embodiments of the present disclosure may be employed. It should be understood that this and other arrangements described herein are set forth only as examples. Other arrangements and elements (e.g., components, interfaces, connections, etc.) can be used in addition to or instead of those shown, and some elements may be omitted altogether for the sake of clarity. In an embodiment, the computing system 200 has components held within a chassis. Various components of the computing system 200 such as the chassis, voltage regulators, memory, or other components are not shown in FIGS. 2A and 2B for simplicity. In addition, certain components of computing system 200 are shown, but are well-known and so will not be discussed in detail. However, the computing system 200, in various embodiments, includes a printed circuit assembly 202 (e.g., a motherboard). In one example, the printed circuit assembly 202 has a top and a bottom (as best seen in FIG. 3).

In an embodiment, the printed circuit assembly 202 has a number of components coupled to it such as a socket 204, an interposer 206, and an adapter board 210. The socket 204, in an embodiment, includes the socket 104, as described above in connection to FIG. 1. However, other types of sockets can be used in connection with the present disclosure. For example, the socket 204 is designed to accept an integrated circuit component that is coupled to the top of the printed circuit assembly 202. In some aspects, the integrated circuit component is a CPU coupled to the printed circuit assembly 202 via a land grid array (LGA) connection. In other aspects, the integrated circuit component is an SoC coupled to the printed circuit assembly via a ball grid array (BGA) connection. As illustrated in FIG. 2B, the integrated circuit component is replaced with the interposer 206 which includes the same configuration of pins (e.g., BGA) as the integrated circuit component that can be coupled to the socket 204. The various components shown in the figures, and discussed herein, are not shown to scale, and may have other shapes, sizes, and configurations, depending on the design of the printed circuit assembly 202.

As seen in FIGS. 2A, 2B, and 3, the interposer 206 is disposed above the socket 204, and connected to the interposer 206 is a connector 208. In an embodiment, the interposer 206 includes a socket lid 334 and a backplate 314. In one example, the interposer 206 includes additional components not shown in FIGS. 2 and 3 for simplicity, such as mounting plates, spacers, or other components to align and mate the interposer with the socket 204 (e.g., the pins within the socket 204). In an embodiment, the socket lid 334 and the backplate 314 provide compression in the direction of the arrow 336 to couple the interposer 206 to the socket 204 (e.g., create a connection between the pins).

Returning to FIGS. 2A and 2B, the adapter board 210, in an embodiment, includes a plurality of components to enable testing of the printed circuit assembly 202. For example, the printed circuit assembly 202 includes a plurality of I/O ports 212A-212C. In an embodiment, the I/O ports 212A-212C are connected to a testing device such as the emulation system 124 described above in connection with FIG. 1. Furthermore, in various embodiments, the adapter board is connected to the interposer 206 via a connector 208. The connector 208, for example, allows communication between the adapter board 210 and the interposer 206 which is connected to the printed circuit assembly 202 via the socket 204.

Turning now to FIGS. 4A and 4B, FIG. 4A shows a perspective view of the printed circuit assembly 202, including the socket 204 and the interposer 206. Furthermore, as illustrated in FIG. 4A, a shim plate 416 is disposed above the interposer 206, and disposed above the shim plate 416 (as seen in FIG. 4B) is a socket lid 420. In one example, the shim plate 416 adds thickness to the interposer 206 to allow the appropriate amount of pressure to establish a connection with the socket 204 when the socket lid 420 is connected to the interposer 206 and/or printed circuit assembly 202. Although the shim plate 416, as illustrated in FIG. 4A, covers the entire top of the interposer 206, other assemblies and/or configurations of the shim plate 416 can be used in connection with the present disclosure.

As illustrated in FIG. 4B, the socket lid 420, in an embodiment, is disposed above the interposer 206 and includes a lever 422 in order to engage a compression mechanism. For example, as a result of depressing the lever 422, a compressive force is applied to the shim plate 416 in order to establish a connection between the interposer 206 and the socket 204. In an embodiment, the socket lid 420 is affixed to the backplate 314, as shown above in FIG. 3. Although not shown in FIG. 4B, the socket lid 420 can include a fan or other cooling mechanism.

FIG. 5A shows a perspective view of an adapter board 510 connected to the interposer 206 with the socket lid 420 disposed over the interposer 206. In an embodiment, the adapter board 510 includes various components to test interfaces or other components of the printed circuit assembly 202. As illustrated in FIG. 5A, the socket lid 420, in some embodiments, obfuscates the connector 208, as shown connected to the adapter board 510 in FIG. 5B. For example, the adapter board 510 is connected to an external protocol tester to provide additional and/or alternative test coverage relative to the emulation system 124 connected to the printed circuit assembly 202

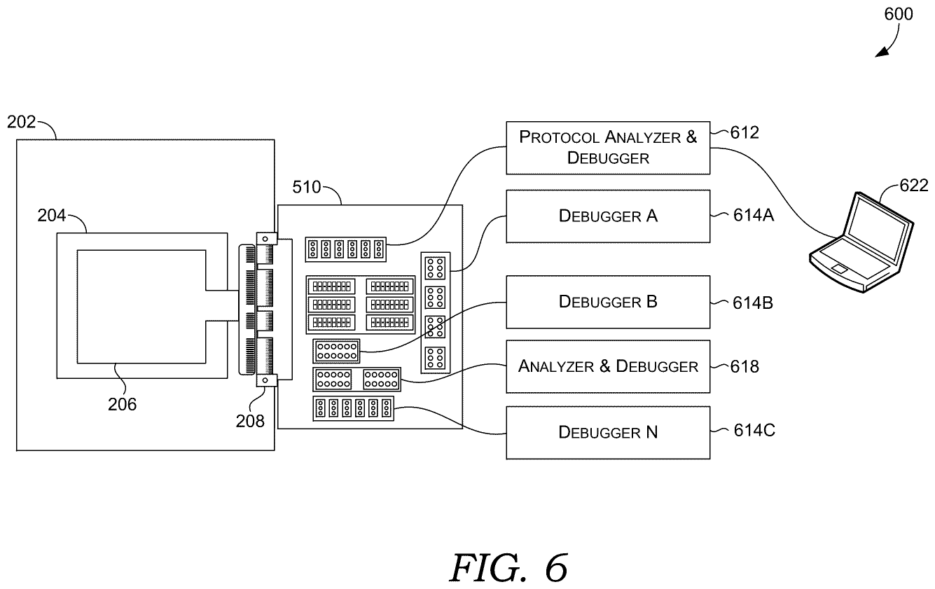

As illustrated in FIG. 6, the environment 600 includes the printed circuit assembly 202, the socket 204, the interposer 206, and the connector 208. Furthermore, in an embodiment, the adapter board 510 includes a protocol analyzer and debugger 612, a set of debuggers 614A-C, and an analyzer debugger 618. In some embodiments, the protocol analyzer and debugger 612, the set of debuggers 614A-C, and the analyzer debugger 618 are connected to a host computer system 622. The host computer system 622 can be any type of computing device, such as the one or more computing devices 800 described in connection with FIG. 8. In some aspects, the adapter board 510 includes various combinations of connectors for communicating with external testing devices in addition to or as an alternative to the protocol analyzer and debugger 612, the set of debuggers 614A-C, and the analyzer debugger 618 illustrated in FIG. 6. Furthermore, in various embodiments, the host computer system 622 can be connected to the printed circuit assembly 202 via the protocol analyzer and debugger 612, the set of debuggers 614A-C, and/or the analyzer debugger 618 in serial or in parallel. For example, the host computer system 622 can be connected to a single connector of the adapter board 510 (e.g., the protocol analyzer and debugger 612, the set of debuggers 614A-C, or the analyzer debugger 618) to test various components of the printed circuit assembly 202. In other examples, the host computer system 622 is simultaneously connected to a plurality of connectors of the adapter board 510 in order to test various components of the printed circuit assembly 202.

In various embodiments, the protocol analyzer and debugger 612, the set of debuggers 614A-C, and the analyzer debugger 618 can be connected to the host computer system 622 to perform various test using different protocols such as Adaptive Voltage Scaling (AVS), Inter-Integrated Circuit (I2C), Improved Inter-Integrated Circuit (I3C), Universal Asynchronous Receiver/Transmitter (UART), and/or Joint Test Action Group (JTAG). For example, the connectors illustrated in FIG. 6 (e.g., the protocol analyzer and debugger 612, the set of debuggers 614A-C, and the analyzer debugger 618) are used to connect the printed circuit assembly 202 to one or more tools (e.g., executed by the host computer system 622) to enable testing, debugging, and/or programming embedded systems which do not have any other debug-capable communications channel.

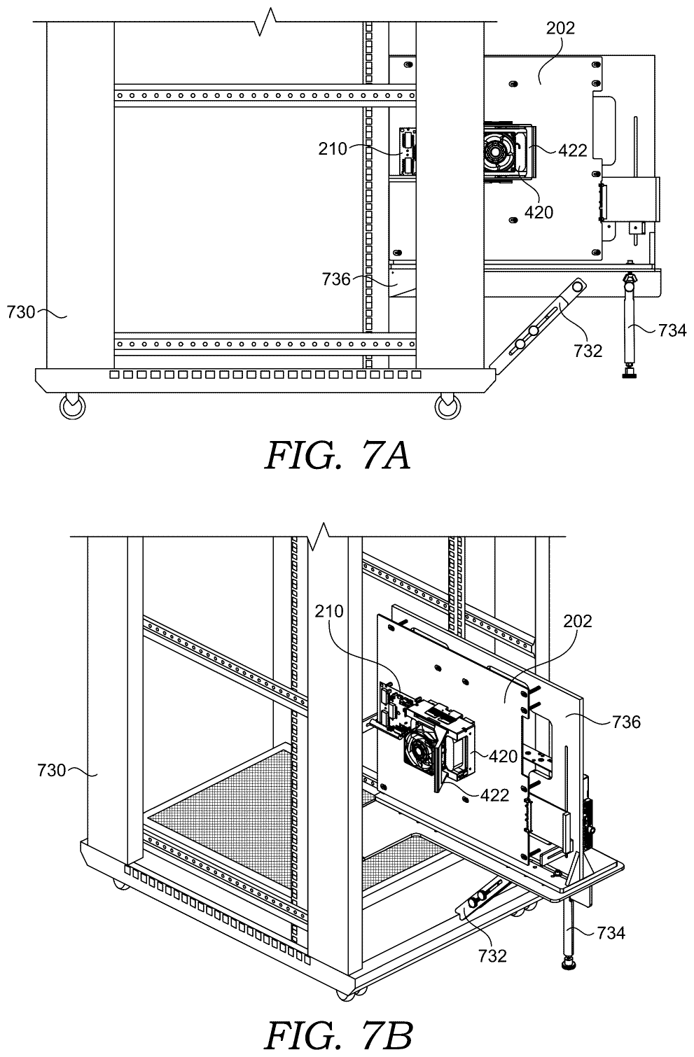

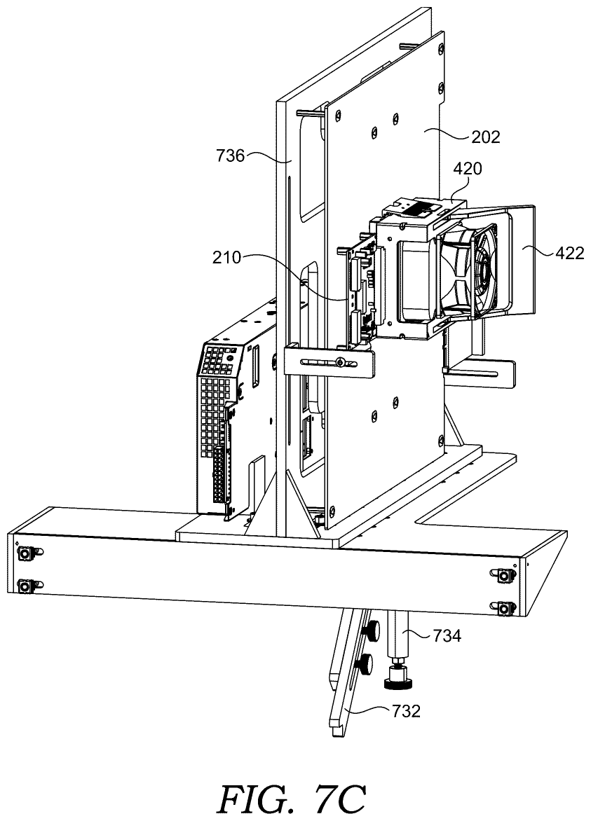

Turning now to FIGS. 7A-8C, FIGS. 7A-7C show several perspective views of a vertical mount 736, which is used to mount the printed circuit assembly 202 of the computing system 200. In various embodiments, the vertical mount 736 is used to enable the printed circuit assembly 202 to be coupled with a server rack 730. In one example, the server rack 730 includes the emulation system 124 described above in connection with FIG. 1. Furthermore, in various embodiments, the vertical mount 736 includes a support beam 732 and a leg 734. In one example, the support beam 732 connects the vertical mount 736 to the server rack 730. Similarly, in an example, the leg 734 extends from the vertical mount 736 and supports the vertical mount 736 (e.g., on a floor). Although not shown in FIGS. 7A-7C for simplicity, one or more cables are used to connect the adapter board to other computing hardware within the server rack 730.

This configuration provides a computing system, such as computing system 200, that allows for the testing of components of the printed circuit assembly 202 prior to the completion of development of an integrated circuit component (e.g., SoC) that the printed circuit assembly 202 (e.g., via the socket 204) is designed to operate with. Furthermore, in such embodiments, by allowing different adapter boards (e.g., adapter board 210 and 510) to be connected to the interposer 206, different types of testing can be performed during development. In one example, an SoC is emulated (e.g., using the emulation system 124) and connected to the printed circuit assembly 202 via adapter board 202, allowing for accurate testing of the printed circuit assembly 202 and various components thereof, including software (e.g., executable instructions) stored in memory of the printed circuit assembly 202, such as firmware.

In another example, adapter board 510 is used to connect the printed circuit assembly 202 to the computer system 622 to additional testing and debugging of various components of the printed circuit assembly 202. Typically, development of computing systems, such as computing systems 200, include a plurality of hardware and software components that have interdependencies, the configurations described above, enable for testing of these interdependencies prior to completing development of certain components, thereby increasing efficiency and reducing development costs and time.

Many different arrangements of the various components depicted, as well as components not shown, are possible without departing from the scope of the claims below. Embodiments of the disclosure have been described with the intent to be illustrative rather than restrictive. Alternative embodiments will become apparent to readers of this disclosure after and because of reading it. Alternative means of implementing the aforementioned can be completed without departing from the scope of the claims below. Certain features and subcombinations are of utility and may be employed without reference to other features and subcombinations and are contemplated within the scope of the claims.

Having described embodiments of the present disclosure, FIG. 8 provides an example of a computing device in which embodiments of the present disclosure may be employed. Computing device 800 includes bus 810 that directly or indirectly couples the following devices: memory 812, one or more processors 814, one or more presentation components 816, input/output (I/O) ports 818, input/output components 820, and illustrative power supply 822. Bus 810 represents what may be one or more buses (such as an address bus, data bus, or combination thereof). Although the various blocks of FIG. 8 are shown with lines for the sake of clarity, in reality, delineating various components is not so clear, and metaphorically, the lines would more accurately be gray and fuzzy. For example, one may consider a presentation component such as a display device to be an I/O component. Also, processors have memory. The inventors recognize that such is the nature of the art and reiterate that the diagram of FIG. 8 is merely illustrative of an exemplary computing device that can be used in connection with one or more embodiments of the present technology. Distinction is not made between such categories as “workstation,” “server,” “laptop,” “handheld device,” etc., as all are contemplated within the scope of FIG. 8 and with reference to “computing device.”

Computing device 800 typically includes a variety of computer-readable media. Computer-readable media can be any available media that can be accessed by computing device 800 and includes both volatile and non-volatile media, removable and non-removable media. By way of example, and not limitation, computer-readable media may comprise computer storage media and communication media. Computer storage media includes both volatile and non-volatile, removable and non-removable media implemented in any method or technology for storage of information such as computer-readable instructions, data structures, program modules, or other data. Computer storage media includes, but is not limited to, RAM, ROM, EEPROM, flash memory or other memory technology, CD-ROM, digital versatile disks (DVDs) or other optical disk storage, magnetic cassettes, magnetic tape, magnetic disk storage or other magnetic storage devices, or any other medium that can be used to store the desired information and which can be accessed by computing device 800. Computer storage media does not comprise signals per se. Communication media typically embodies computer-readable instructions, data structures, program modules, or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media, such as a wired network or direct-wired connection, and wireless media, such as acoustic, RF, infrared, and other wireless media. Combinations of any of the above should also be included within the scope of computer-readable media.

Memory 812 includes computer storage media in the form of volatile and/or non-volatile memory. As depicted, memory 812 includes instructions 824. Instructions 824, when executed by processor(s) 814, are configured to cause the computing device to perform any of the operations described herein, in reference to the above discussed figures, or to implement any program modules described herein. The memory may be removable, non-removable, or a combination thereof. Exemplary hardware devices include solid-state memory, hard drives, optical-disc drives, etc. Computing device 800 includes one or more processors that read data from various entities such as memory 812 or I/O components 820. Presentation component(s) 816 present data indications to a user or other device. Exemplary presentation components include a display device, speaker, printing component, vibrating component, etc.

I/O ports 818 allow computing device 800 to be logically coupled to other devices including I/O components 820, some of which may be built-in. Illustrative components include a microphone, joystick, game pad, satellite dish, scanner, printer, wireless device, etc. I/O components 820 may provide a natural user interface (NUI) that processes air gestures, voice, or other physiological inputs generated by a user. In some instances, inputs may be transmitted to an appropriate network element for further processing. An NUI may implement any combination of speech recognition, touch and stylus recognition, facial recognition, biometric recognition, gesture recognition both on screen and adjacent to the screen, air gestures, head and eye tracking, and touch recognition associated with displays on computing device 800. Computing device 800 may be equipped with depth cameras, such as stereoscopic camera systems, infrared camera systems, RGB camera systems, and combinations of these, for gesture detection and recognition. Additionally, computing device 800 may be equipped with accelerometers or gyroscopes that enable detection of motion. The output of the accelerometers or gyroscopes may be provided to the display of computing device 800 to render immersive augmented reality or virtual reality.

Embodiments presented herein have been described in relation to particular embodiments, which are intended in all respects to be illustrative rather than restrictive. Alternative embodiments will become apparent to those of ordinary skill in the art to which the present disclosure pertains without departing from its scope.

Various aspects of the illustrative embodiments have been described using terms commonly employed by those skilled in the art to convey the substance of their work to others skilled in the art. However, it will be apparent to those skilled in the art that alternate embodiments may be practiced with only some of the described aspects. For purposes of explanation, specific numbers, materials, and configurations are set forth in order to provide a thorough understanding of the illustrative embodiments. However, it will be apparent to one skilled in the art that alternate embodiments may be practiced without the specific details. In other instances, well-known features have been omitted or simplified in order not to obscure the illustrative embodiments.

Various operations have been described as multiple discrete operations, in turn, in a manner that is most helpful in understanding the illustrative embodiments; however, the order of description should not be construed as to imply that these operations are necessarily order dependent. In particular, these operations need not be performed in the order of presentation. Further, descriptions of operations as separate operations should not be construed as requiring that the operations be necessarily performed independently and/or by separate entities. Descriptions of entities and/or modules as separate modules should likewise not be construed as requiring that the modules be separate and/or perform separate operations. In various embodiments, illustrated and/or described operations, entities, data, and/or modules may be merged, broken into further sub-parts, and/or omitted.

The phrase “in one embodiment” or “in an embodiment” is used repeatedly. The phrase generally does not refer to the same embodiment; however, it may. The terms “comprising,” “having,” and “including” are synonymous, unless the context dictates otherwise. The phrase “A/B” means “A or B.” The phrase “A and/or B” means “(A), (B), or (A and B).” The phrase “at least one of A, B, and C” means “(A), (B), (C), (A and B), (A and C), (B and C), or (A, B and C).”

### EXAMPLE EMBODIMENTS

The following embodiments represent example literal support clauses and embodiments of concepts contemplated herein. Any one of the following embodiments may be combined in a multiple dependent manner to depend from one or more other embodiments. Further, any combination of dependent embodiments (e.g., clauses that explicitly depend from a previous embodiment) may be combined while staying within the scope of aspects contemplated herein. The following embodiments are exemplary in nature and are not limiting.

In some embodiments, an emulation system comprises an integrated circuit socket configured for coupling to a printed circuit assembly and to accept an integrated circuit component, the integrated circuit socket including a socket back plate for coupling to the printed circuit assembly and a socket lid coupled to the top of the integrated circuit socket; at least one electronic component configured for coupling to the printed circuit assembly; an adapter board configured for coupling to a computing system operating an emulation application; and an interposer coupled to the integrated circuit socket so that, when the integrated circuit socket is coupled to the printed circuit assembly, the interposer is positioned between the printed circuit assembly and the socket lid, the interposer including a connector to accept the adapter board.

In any combination of the above embodiments of the emulation system, wherein the at least one electronic component is a voltage regulator.

In any combination of the above embodiments of the emulation system, further comprising: a shim plate between the interposer and the socket lid, the shim plate provides additional thickness to the interposer to allow the socket lid to apply an amount of compressive force to engage pins of the integrated circuit socket; and wherein the socket lid further comprises a plurality of springs and a lever that compresses the plurality of springs to apply a force to the shim plate to secure the interposer within the integrated circuit socket.

In any combination of the above embodiments of the emulation system, wherein the adapter board further comprises ribbon cables connected to the connected to enable communication between the computing system and the printed circuit assembly.

In any combination of the above embodiments of the, wherein the ribbon cable is connected to the computing system, and wherein the computing system includes a plurality of field-programmable gate arrays (FPGAs).

In any combination of the above embodiments of the emulation system, wherein the plurality of FPGAs of the computing system emulate a System on Chip (SoC).

In any combination of the above embodiments of the emulation system, wherein the emulated SoC corresponds to a physical SoC, and wherein the integrated circuit socket is configured to accept the physical SoC as the integrated circuit component.

In any combination of the above embodiments of the emulation system, wherein the adapter board further comprises a second electronic component for testing the at least one electronic component configured for coupling to the printed circuit assembly.

In any combination of the above embodiments of the emulation system, wherein the at least one electronic component includes at least one of a voltage regulator, a chipset, an interface, a port, memory, a power connector, a socket, and firmware.

In any combination of the above embodiments of the emulation system, wherein the integrated circuit socket includes an array of pins and wherein the interposer includes a set of contact elements that align and mate the interposer with the array of pins of the integrated circuit socket.

In any combination of the above embodiments of the emulation system, further comprising a component for capturing data associated with operation of the emulation application so that optimizations can be made to the integrated circuit component.

In some embodiments, a computing system, comprises a processor; memory storing executable instructions that, as a result of being executed by the processor, cause the processor to perform operation comprising: emulating an integrated circuit component; and transmitting, during a testing operation of a first electronic component, data to a printed circuit assembly via an adapter board connected to the printed circuit assembly by an interposer; and the printed circuit assembly having a socket to accept the interposer, the first electronic component coupled to the printed circuit assembly, wherein the interposer includes a connector to accept the adapter board that communicates with the integrated circuit component.

In any combination of the above embodiments of the computing system, wherein the socket further comprises a socket back plate coupled to a back of the printed circuit assembly and a socket lid coupled to a top of the printed circuit assembly.

In any combination of the above embodiments of the computing system, wherein emulating the integrated circuit component further comprises emulating a SoC.

In any combination of the above embodiments of the computing system, further comprising a vertical mount coupled to the printed circuit assembly to affix the printed circuit assembly to a server rack containing the computing system.

In any combination of the above embodiments of the computing system, wherein the adapter board further comprises an I/O port connected to the processor.

In any combination of the above embodiments of the computing system, wherein transmitting the data to the printed circuit assembly further comprises transmitting the data via the I/O port to the adapter board.

In any combination of the above embodiments of the computing system, the connector includes a straddle mount connector.

In some embodiments, a system for emulating a computer system on a chip (SOC) comprises a socket configured for coupling, to a printed circuit assembly, an integrated circuit component, the socket including a socket back plate for coupling to the printed circuit assembly and a socket lid coupled to the top of the socket; an adapter board configured for coupling to a computing system operating an emulation application including a plurality of field-programmable gate arrays (FPGAs) to emulate the integrated circuit component, the adapter board including a first electronic component for testing a second electronic component configured for coupling to the printed circuit assembly; and an interposer coupled to the socket such that the interposer is positioned between the printed circuit assembly and the socket lid, the interposer including a connector to accept the adapter board.

In any combination of the above embodiments of the system, wherein the plurality of FPGAs of the computing system emulate a System on Chip (SoC) corresponding to a physical SoC; and wherein the socket is configured to accept the physical SoC as the integrated circuit component.

What is claimed is:

1. An emulation system, comprising:
an integrated circuit socket configured for coupling to a printed circuit assembly and to accept an integrated circuit component, the integrated circuit socket including a socket back plate for coupling to the printed circuit assembly and a socket lid coupled to the top of the integrated circuit socket;
at least one electronic component configured for coupling to the printed circuit assembly;
an adapter board configured for coupling to a computing system operating an emulation application; and
an interposer coupled to the integrated circuit socket so that, when the integrated circuit socket is coupled to the printed circuit assembly, the interposer is positioned between the printed circuit assembly and the socket lid, the interposer including a connector to accept the adapter board.

2. The emulation system of claim 1, wherein the at least one electronic component is a voltage regulator.

3. The emulation system of claim 1, further comprising:
a shim plate between the interposer and the socket lid, the shim plate provides additional thickness to the interposer to allow the socket lid to apply an amount of compressive force to engage pins of the integrated circuit socket; and
wherein the socket lid further comprises a plurality of springs and a lever that compresses the plurality of springs to apply a force to the shim plate to secure the interposer within the integrated circuit socket.

4. The emulation system of claim 1, wherein the adapter board further comprises ribbon cables connected to the connected to enable communication between the computing system and the printed circuit assembly.

5. The emulation system of claim 4, wherein the ribbon cable is connected to the computing system, and wherein the computing system includes a plurality of field-programmable gate arrays (FPGAs).

6. The emulation system of claim 5, wherein the plurality of FPGAs of the computing system emulate a System on Chip (SoC).

7. The emulation system of claim 6, wherein the emulated SoC corresponds to a physical SoC, and wherein the integrated circuit socket is configured to accept the physical SoC as the integrated circuit component.

8. The emulation system of claim 1, wherein the adapter board further comprises a second electronic component for testing the at least one electronic component configured for coupling to the printed circuit assembly.

9. The emulation system of claim 8, wherein the at least one electronic component includes at least one of a voltage regulator, a chipset, an interface, a port, memory, a power connector, a socket, and firmware.

10. The emulation system of claim 1, wherein the integrated circuit socket includes an array of pins and wherein the interposer includes a set of contact elements that align and mate the interposer with the array of pins of the integrated circuit socket.

11. The emulation system of claim 1, further comprising a component for capturing data associated with operation of the emulation application so that optimizations can be made to the integrated circuit component.

12. A computing system, comprising:
a processor;
memory storing executable instructions that, as a result of being executed by the processor, cause the processor to perform operation comprising:
emulating an integrated circuit component; and
transmitting, during a testing operation of a first electronic component, data to a printed circuit assembly via an adapter board connected to the printed circuit assembly by an interposer; and
the printed circuit assembly having a socket to accept the interposer, the first electronic component coupled to the printed circuit assembly, wherein the interposer includes a connector to accept the adapter board that communicates with the integrated circuit component.

13. The computing system of claim 12, wherein the socket further comprises a socket back plate coupled to a back of the printed circuit assembly and a socket lid coupled to a top of the printed circuit assembly.

14. The computing system of claim 12, wherein emulating the integrated circuit component further comprises emulating a SoC.

15. The computing system of claim 12, further comprising a vertical mount coupled to the printed circuit assembly to affix the printed circuit assembly to a server rack containing the computing system.

16. The computing system of claim 12, wherein the adapter board further comprises an I/O port connected to the processor.

17. The computing system of claim 16, wherein transmitting the data to the printed circuit assembly further comprises transmitting the data via the I/O port to the adapter board.

18. The computing system of claim 12, the connector includes a straddle mount connector.

19. A system for emulating a computer system on a chip (SOC) comprising:
a socket configured for coupling, to a printed circuit assembly, an integrated circuit component, the socket including a socket back plate for coupling to the printed circuit assembly and a socket lid coupled to the top of the socket;
an adapter board configured for coupling to a computing system operating an emulation application including a plurality of field-programmable gate arrays (FPGAs) to emulate the integrated circuit component, the adapter board including a first electronic component for testing a second electronic component configured for coupling to the printed circuit assembly; and
an interposer coupled to the socket such that the interposer is positioned between the printed circuit assembly and the socket lid, the interposer including a connector to accept the adapter board.

20. The system of claim 19, wherein the plurality of FPGAs of the computing system emulate a System on Chip (SoC) corresponding to a physical SoC; and
wherein the socket is configured to accept the physical SoC as the integrated circuit component.
